(19) United States
(12) Patent Application Publication
(10) Pub. No.: US 2017/0287717 A1
(43) Pub. Date: Oct. 5, 2017

(54) ENGINEERED ETCHED INTERFACES FOR HIGH PERFORMANCE JUNCTIONS

(71) Applicant: International Business Machines Corporation, Armonk, NY (US)

(72) Inventors: Robert L. BRUCE, White Plains, NY (US); Hiroyuki MIYAZOE, White Plains, NY (US); John ROZEN, Hastings on Hudson, NY (US)

(21) Appl. No.: 15/087,030

(22) Filed: Mar. 31, 2016

(51) Int. Cl. H01L 21/28; H01L 29/51; H01L 21/3213; H01L 21/311; H01L 21/02

(52) U.S. Cl. CPC H01L 21/28158; H01L 21/31116; H01L 21/02065; H01L 21/02074; H01L 21/32135; H01L 21/0228; H01L 29/517; H01L 21/28026; H01L 21/02178; H01L 21/02181; H01L 21/02192; H01L 21/02123; H01L 21/02164; H01L 21/02167; H01L 21/0217

(57) ABSTRACT

Various methods for fabricating a semiconductor device by selective in-situ cleaning of a target surface of a semiconductor substrate by selective dry surface atomic layer etching of the target surface film, selectively removing one or more top layers of atoms from the target surface film of the semiconductor substrate. The selective in-situ cleaning of a target surface can be followed by deposition on the cleaned target surface such as to form a cap layer, a conductive contact layer, or a gate dielectric layer.

### BACKGROUND OF THE INVENTION

The present disclosure generally relates to the field of semiconductors, and more particularly relates to a method of fabricating semiconductor interfaces, junctions, and contacts.

Obtaining a pristine and/or passivated semiconductor surface without damaging the bulk of the film is critical to gate stack and contact formation in order to improve transfer characteristics (mobility, sub-threshold slope, etc.) and reduce resistivity, respectively.

This is particularly challenging for high-mobility semiconductors (such as InGaAs & SiGe) for which a low quality native oxide readily forms after air exposure so that wet chemistry is not sufficient to condition the substrate appropriately. This also adds a queue-time dependence between wet chemical treatment and dielectric gate or metal contact deposition so that the integration is rendered non-practical in a manufacturing setting.

On III-V substrates, proposed solutions are limited due to, for example, the small process compatibility window (e.g. temperature up to 400 C). Sulfur-containing chemistry only slows oxide regrowth and yields downstream tool contamination. Interface scavenging deposition methods such as those involving AlO-containing gate stacks are not applicable to contacts and yield low dielectric constant material in the gate stack which affects capacitance scaling. Remote plasma converted inter-layers (insertion of Al or Ti and/or N) comprise a non-selective process that converts the native oxide, can create etch damage in the channel region, and is not likely applicable to contacts due to the presence of oxygen in the resulting film.

### SUMMARY OF THE INVENTION

Various embodiments of the present invention consist of in-situ sequential use of atomically controlled layer etching (aka Atomic Layer Etching—ALE, molecular layer etching, digital etching, layer-by-layer etching) not for patterning but as a surface conditioning method to remove a semiconductor interface layer prior to dielectric gate stack deposition or metal contact formation.

Use of such a method for surface preparation can take advantage of its self-limiting quality for a high degree of control preventing damage in a sensitive channel or contact. The method can also take advantage of its selectivity for stopping on the semiconductor layer. Furthermore, the method can be used as an additional knob in CMOS integration to reduce the number and complexity of patterning levels. It is combined with subsequent in-situ interlayer formation, dielectric gate stack deposition, metal contact formation, or epi-regrowth (e.g. raised S/D) in order to avoid the regrowth of a poor interface due to ambient exposure, which is particularly applicable for SiGe & III-V materials (e.g., InGaAs).

In one embodiment, a method for fabricating a semiconductor device comprises: selective in-situ cleaning of a target surface of a semiconductor substrate by selective dry surface atomic layer etching of the target surface layer, selectively removing one or more top layers of atoms from the target surface.

In another embodiment, a process of fabricating a semiconductor integrated circuit comprises at least: selective in-situ cleaning of a surface of a high-mobility substrate by selective dry surface atomic layer etching of the surface layer, selectively removing one or more top layers of atoms from the surface; and forming directly on the in-situ cleaned surface of the high-mobility substrate, at least one of: a cap layer (for further ex-situ processing); a conductive contact layer; epi re-growth; or a gate dielectric layer.

In yet another embodiment, a method for fabricating a semiconductor device comprises: selective in-situ cleaning of a target surface of a semiconductor substrate that selectively removes one or more top layers of atoms from the target surface by: exposing in-situ the target surface to a controlled precursor gas pulse; optionally purging, after the exposing to the precursor gas pulse,; and exposing in-situ the target surface to energetic particles to selectively desorb the one or more top layers of atoms from the target surface. Subsequent in-situ deposition techniques will maintain integrity of the prepared surface. The interlayer formation or subsequent layer deposition can be achieved by at least one of the following: chemical vapor deposition, plasma-enhanced chemical vapor deposition, atomic layer deposition, plasma-enhanced atomic layer deposition, sputtering, or thermal/e-beam evaporation.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 is a block diagram illustrating an example of a gate stack interface cleaning and/or surface conditioning process using in-situ atomic layer etching and in-situ atomic layer deposition, according to one embodiment of the present disclosure;

FIG. 2 is an operational flow diagram illustrating an example process for selective atomic layer etching of a semiconductor substrate surface layer, according to an embodiment of the present disclosure; and

FIG. 3 is an operational flow diagram illustrating an example process including the process for selective atomic layer etching of a semiconductor substrate surface layer as shown in FIG. 2, and further including process steps for in-situ deposition on the semiconductor substrate surface, according to an embodiment of the present disclosure.

### DETAILED DESCRIPTION

It is to be understood that the present disclosure will be described in terms of a given illustrative example process for surface conditioning of semiconductor interfaces, junctions, and contacts. However, other semiconductor architectures, structures, substrate materials, and process features and steps may be varied within the scope of the present disclosure.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The present embodiments may include a design for an integrated circuit chip, which may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used as part of a process in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

Various embodiments of the present invention consist of in-situ sequential use of atomically controlled layer etching (aka Atomic Layer Etching—ALE, molecular layer etching, digital etching, layer-by-layer etching) not for patterning but as a surface conditioning method to remove or clean a semiconductor interface layer prior to dielectric gate stack or metal contact formation.

Use of such a method for surface preparation can take advantage of its self-limiting quality for a high degree of control preventing damage in a sensitive channel or contact. The method can also take advantage of its selectivity for stopping on the semiconductor layer. Furthermore, the method can be combined with subsequent in-situ interlayer formation, dielectric gate stack deposition, metal contact formation, or epi-regrowth (e.g. raised S/D) in order to avoid the regrowth of a poor interface due to ambient exposure, which is particularly applicable for SiGe & III-V.

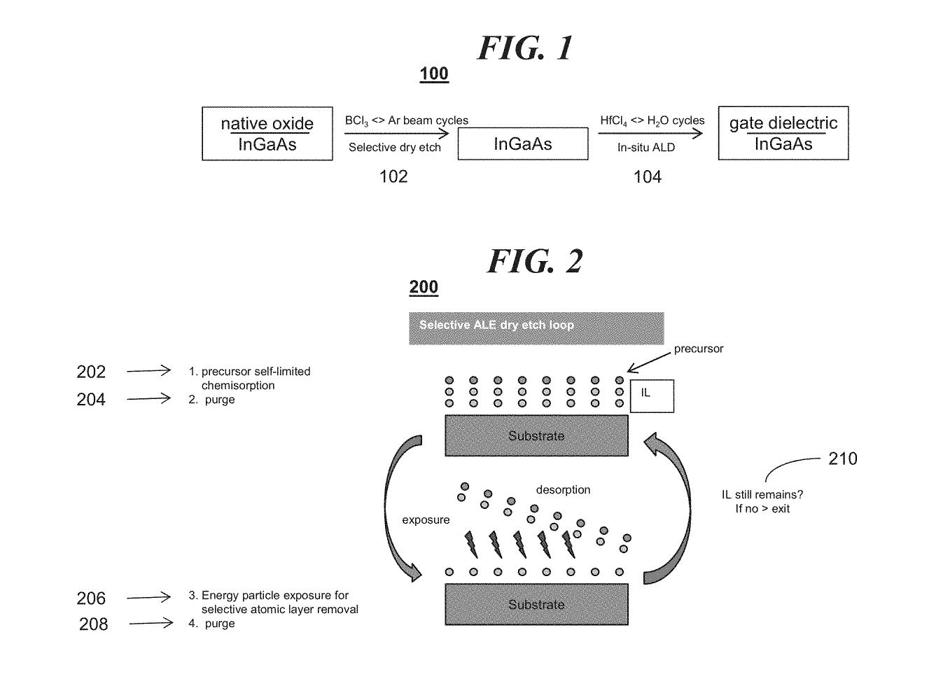

Referring now to the drawings in which like numerals represent the same of similar elements, FIGS. 1-3 illustrate several example processes for fabricating semiconductor devices and their interfaces, interconnects, junctions, contacts, and the like.

FIG. 1 shows an example process 100 in which a surface of an incoming substrate, such as a gate stack interface, is cleaned by selective dry surface etching 102 prior to an optional in-situ dielectric film growth by atomic layer deposition 104. The selective dry surface etching 102 comprises removal of (O, C, semiconductor oxide, etc.) from one or more top layers of atoms of the surface. The process 100 can form an intentional interface layer, a capping layer, a gate dielectric layer, or a conductive contact layer which may consist of metal or epi regrowth. The entire process sequence 100 can be performed in-situ (e.g., for III-V, SiGe, etc.). In the particular example shown in FIG. 1, the substrate comprises InGaAs and the process comprises in-situ cleaning of a surface of an interface of the substrate followed by formation of a gate stack on the cleaned surface.

The dry surface clean consist of a set of repeated cycles consisting of four distinct steps: First, a precursor pulse (self-saturated chemisorption on target surface) is applied to the surface. Second, an optional purge is performed to remove all chemical vapor from the surface region. Third, the process includes exposure of the surface to energetic particles, which energy is tailored to selectively desorb the one or more top layers of atoms linked to the precursor without inducing etch damage. Finally, in a fourth step, a second purge is performed to remove all chemical vapor from the surface region. This process 100 leaves the surface of the semiconductor cleaned and conditioned, ready for subsequent semiconductor fabrication processing.

The precursor, used in the example process 100, is a gas partially consisting of the molecular, atomic or plasma forms of, for example, at least one of the following: BCl₃, Cl₂, Ar, O₂, CF₄, NF₃, F₂, He, N₂, CₓF_{y}, CₓH_{y}F_{z}, H2, CH4, SF₆, phosphine, arsine, TMA, HfCl₄, or TiCl₄. The given list of possible precursor chemistry is only provided as an example process.

The energetic particle can be a photon, a neutral or a charged form of at least one of the following: electron, Ar, Ne, He, or any of the other precursors mentioned above.

The interlayer formation or subsequent layer deposition can be achieved by at least one of the following: chemical vapor deposition, plasma-enhanced chemical vapor deposition, atomic layer deposition, plasma-enhanced atomic layer deposition, sputtering, or thermal/e-beam evaporation. Such methods can preserve the prepared surface obtained by in-situ atomic layer etching. For example, a gate dielectric of up to 50 A in thickness can be deposited on InGaAs at 300 C using atomic layer deposition of Al₂O₃ and/or HfO₂ using precursors such as, but not limited to: TMA, HfCl₄, TEMA-Hf, H₂O. Another example would be deposition of a metal contact on InGaAs of up to 1000 A using an evaporation method of elements such as, but not limited to: Ti, Pd, Au. The metal contact formation can optionally be preceded by a highly-doped epi-regrowth on the semiconductor surface.

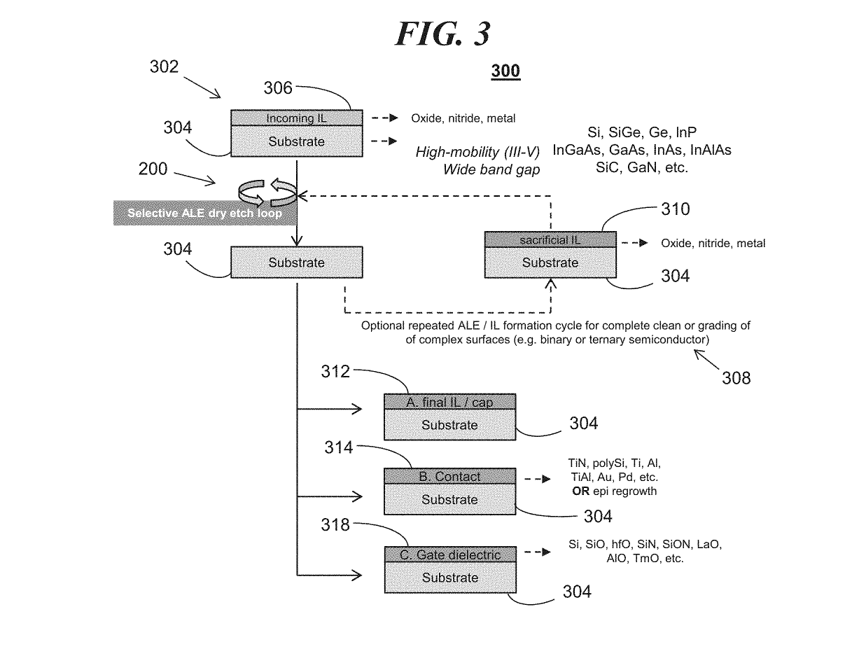

The combination of FIGS. 2 and 3 illustrates a semiconductor fabrication process, according to various embodiments. FIG. 3 shows a process 300 including the selective atomic level etching process 200, which is shown in more detail in FIG. 2, and further including selective in-situ atomic level deposition on the semiconductor device 302.

FIG. 2 shows a portion of the fabrication process illustrated in FIG. 3 in which a target surface layer (or can also be referred to as surface layer film, interlayer film, or surface film) 306 on a surface of the substrate 304 of the semiconductor device 302 is removed using an atomic level etching process 200. Such substrate 304 can be prepared by growing a semiconductor material layer on a seed layer located on the surface of a wafer. In this example, the semiconductor substrate 304 comprises InGaAs. The target surface layer film 306 can be removed using selective atomic level dry etching of the target layer film 306 thereby “cleaning” the surface of the substrate 304. The selective atomic level dry etching of the target layer film 306 repeats in a process loop, as shown in FIG. 2, until the target layer film 306 is determined to be completely removed, at step 210.

Initially, as shown in FIG. 3, the incoming semiconductor device 302 has a surface layer (or interlayer film) 306 that comprises oxide, nitride, or metal. The surface layer 306 comprises at least one layer directly atop the substrate 304 of the semiconductor device 302. The device 302 can comprise a substrate of, for example, any of Si, SiGe, Ge, or InGaAs materials composition. It could also comprise a substrate of, for example, any of InGaAs, GaAs, InAs, InAlAs, InP, and any other high-mobility (III-V) materials composition. It also could comprise a substrate of, for example, any of SiC, GaN, etc., and any other wide band gap materials composition. Such substrate (or can also be referred to as substrate layer) 304 can also comprise a semiconductor material layer on a seed layer located on the surface of a wafer.

The incoming semiconductor device 302 is processed using the selective atomic level dry etching process 200 shown in FIG. 2. The selective dry surface etching process 200 consists of a set of repeated cycles consisting of four distinct steps. First, at step 202, a precursor pulse (self-saturated self-limited chemisorption on the target surface) is applied to the surface layer (or interlayer film) 306 which is the target of the surface layer 306 removal and conditioning treatment. Second, at step 204, an optional purge is performed to remove all chemical vapor and gases from the region surrounding the target surface 306. Third, at step 206, the process includes exposure of the target surface 306 to energetic particles to selectively desorb and remove the top layer of atoms linked to the precursor without inducing etch damage. In a fourth step, at step 208, a second purge is performed to remove all chemical vapor and gases from the region surrounding the target surface layer 306. Lastly, at step 210, it is determined whether any, according to the present example, oxide, nitride, or metal composition at the top one or more layers of atoms remain on the target surface layer 306. If one or more layers of atoms remain on the target surface 306, as step 210, the process repeats the selective atomic level dry etching process loop 200. The process loop 200 is repeated until the target surface layer 306 is determined, at step 210, to be completely removed. This process 200 leaves the surface of the substrate 304 cleaned and/or conditioned, ready for subsequent semiconductor fabrication processing. This surface cleaning and/or conditioning process 200 can be performed with the semiconductor substrate 304 being in situ.

After the target surface layer 306 is determined, at step 210, to be completely removed, the semiconductor device 302 with a cleaned and/or conditioned surface on the substrate 304 can be subjected to various additional semiconductor fabrication process steps.

According to certain embodiments, as shown in FIG. 3, at step 308 a semiconductor fabrication process can optionally form a layer (e.g., a layer of oxide, nitride, metal, etc., depending on the particular fabrication process) as a sacrificial layer 310 on the interface surface of the substrate 304. The process 300 then performs the selective atomic level dry etching loop 200 to clean and/or condition the interface surface of the substrate 304 including removal of the sacrificial layer 310. The sequence of forming a sacrificial layer 310 on the interface surface of the substrate 304 followed by performing atomic level dry etching to clean and/or condition the interface surface of the substrate 304, including removal of the sacrificial layer 310, can be repeated until completely cleaning, conditioning, and/or grading a complex surface (e.g. binary or ternary semiconductor) of the substrate 304 of the semiconductor device 302.

The cleaned and conditioned interface surface of the substrate 304 may be further processed in the semiconductor fabrication process 300 to add at least a film on the surface of the substrate 304. For example, the fabrication process 300 can add a cap layer 312 on the interface surface of the substrate 304 (e.g. for further ex-situ processing). As a second example, the fabrication process 300 can add a conductive contact layer 314 (e.g., a layer comprising TiN, polySi, Ti, Al, TiAl, Au, Pd, etc., or epi regrowth) on the interface surface of the substrate 304. As a third example, the fabrication process 300 can add a gate dielectric layer 318 (e.g., a layer comprising Si, SiO2, HfO2, SiN, SiON, La2O3, Al203, Tm2O3, etc.) on the surface of the substrate 304. For example, this can form a channel for a gate stack of a semiconductor device or a semiconductor integrated circuit.

Although specific embodiments of the disclosure have been disclosed, those having ordinary skill in the art will understand that changes can be made to the specific embodiments without departing from the spirit and scope of the disclosure. The scope of the disclosure is not to be restricted, therefore, to the specific embodiments, and it is intended that the appended claims cover any and all such applications, modifications, and embodiments within the scope of the present disclosure.

It should be noted that some features of the present disclosure may be used in one embodiment thereof without use of other features of the present disclosure. As such, the foregoing description should be considered as merely illustrative of the principles, teachings, examples, and exemplary embodiments of the present disclosure, and not a limitation thereof.

Also these embodiments are only examples of the many advantageous uses of the innovative teachings herein. In general, statements made in the specification of the present application do not necessarily limit any of the various claimed disclosures. Moreover, some statements may apply to some inventive features but not to others.

1. A method for fabricating a semiconductor device, the method comprising:
selective in-situ cleaning and/or conditioning of an interface surface of a semiconductor substrate by
applying a controlled self-saturated self-limited chemisorption precursor gas pulse on the interface surface;
purging, after the applying, substantially all gas from a region directly surrounding the interface surface; and
exposing, after the purging, the interface surface to energetic particles to perform selective in-situ cleaning and/or conditioning by dry surface atomic layer etching of the interface surface of the semiconductor substrate thereby selectively removing one or more top layers of atoms from the interface surface of the semiconductor substrate, the one or more top layers of atoms having been linked to a precursor applied thereto by the precursor gas pulse, in preparation for the interface surface of the semiconductor substrate being then further processed by in-situ depositing at least a layer on the cleaned and/or conditioned interface surface.

2. The method of claim 1, comprising selectively removing one or more top layers of oxide from the surface of the semiconductor substrate.

3. The method of claim 1, comprising selectively removing one or more top layers of nitride from the surface of the semiconductor substrate.

4. The method of claim 1, comprising selectively removing one or more top layers of metal from the surface of the semiconductor substrate.

5. The method of claim 1, comprising:
repeating the selective in-situ cleaning and/or conditioning of the surface followed by determining whether the surface has been cleaned and/or conditioned, until determining that the selectively removing one or more top layers of atoms from the surface has completely cleaned and/or conditioned the surface of the semiconductor substrate.

6. The method of claim 1, wherein the selective in-situ cleaning and/or conditioning of the surface is performed before forming a gate dielectric layer on the cleaned and/or conditioned surface of the semiconductor substrate.

7. The method of claim 6, further comprising:
forming a gate dielectric layer on the cleaned and/or conditioned surface of the semiconductor substrate.

8. The method of claim 1, wherein the surface is a complex surface of the semiconductor substrate, and the method further comprising:
after the selective in-situ cleaning and/or conditioning of the complex surface of the semiconductor substrate, forming a sacrificial layer on the complex surface; and
repeating the forming of a sacrificial layer on the complex surface followed by selective in-situ cleaning and/or conditioning of the complex surface until determining that the selectively removing one or more top layers of atoms from the complex surface has at least one of
completely cleaned and/or conditioned the complex surface; or
completely graded the complex surface.

9. The method of claim 1, further comprising:
after the selective in-situ cleaning and/or conditioning of the surface of the semiconductor substrate:
forming a gate dielectric layer directly on the cleaned and/or conditioned surface of the semiconductor substrate.

10. The method of claim 1, wherein the semiconductor substrate is a high-mobility semiconductor substrate or comprises a high-mobility semiconductor atop a seed layer at the surface of a semiconductor substrate.

11. The method of claim 10, further comprising:
after the selective in-situ cleaning and/or conditioning of the surface of the high-mobility semiconductor substrate:
forming a gate dielectric layer directly on the cleaned and/or conditioned surface of the high-mobility semiconductor substrate.

12. The process of claim 1, wherein the semiconductor substrate comprises at least one of the following materials composition: Si, SiGe, Ge, InGaAs, GaAs, InAs, InAlAs, lnP, SiC, and GaN.

13. A process of fabricating a semiconductor integrated circuit comprising at least:
selective in-situ cleaning of an interface surface of a III-V high-mobility semiconductor substrate by
applying a controlled self-saturated self-limited chemisorption precursor gas pulse on the interface surface;
purging, after the applying, substantially all gas from a region directly surrounding the interface surface; and
exposing, after the purging, the interface surface to energetic particles to perform selective in-situ cleaning by dry surface atomic layer etching of the interface surface by selectively removing one or more top layers of atoms from the interface surface, the one or more top layers of atoms having been linked to a precursor applied thereto by the precursor gas pulse; and
in-situ forming directly on the in-situ cleaned interface surface of the III-V high-mobility semiconductor substrate:
a gate dielectric layer.

14. The process of claim 13, wherein the III-V high-mobility semiconductor substrate comprises at least one of:
InGaAs;
GaAs;
InAs;
InAlAs; or
lnP.

15. A method for fabricating a semiconductor device, the method comprising:
selective in-situ cleaning of a target surface of a semiconductor substrate by selectively removing one or more top layers of atoms from the target surface by:
exposing in-situ the target surface to a controlled self-saturated self-limited chemisorption precursor gas pulse thereby applying precursor from the precursor gas pulse to the target surface;
purging, after the exposing to the precursor gas pulse, substantially all gas from a region directly surrounding the target surface; and
exposing, after the purging, in-situ the target surface to energetic particles to selectively in-situ clean the target surface by desorbing the one or more top layers of atoms linked to the precursor from the precursor gas pulse; and
followed by in-situ deposition of a layer on the in-situ cleaned target surface.

16. The method of claim 15, further comprising:
after the selective in-situ cleaning of the target surface, performing a deposition selected from the following set:
performing in-situ deposition on the in-situ cleaned target surface to form a conductive contact layer on the cleaned target surface of the semiconductor substrate; and
performing in-situ deposition on the in-situ cleaned target surface to form a gate dielectric layer on the cleaned target surface of the semiconductor substrate.

17. The method of claim 15, further comprising:
after the selective in-situ cleaning of the target surface, performing in-situ deposition on the cleaned target surface to form a gate dielectric layer on the in-situ cleaned target surface of the semiconductor substrate.

18. The method of claim 17, wherein the deposition comprises atomic layer deposition of one or more layers of dielectrics to form a gate, the dielectrics deposited by atomic layer deposition comprising at least one of: Al2O3;HfO2; Si; SiO2; La2O3; Tm2O3; SiN; or SiC.

19. The method of claim 15, wherein the target surface is a complex target surface, and the method further comprising:
forming, prior to selective in-situ cleaning of the complex target surface of the semiconductor substrate, a sacrificial layer on the complex target surface;
selective in-situ cleaning of the complex target surface, including the sacrificial layer disposed thereon, by selectively removing the sacrificial layer and one or more top layers of atoms from the complex target surface by:
exposing in-situ the sacrificial layer and the complex target surface to a controlled self-saturated self-limited chemisorption precursor gas pulse thereby applying precursor from the precursor gas pulse to the sacrificial layer and the complex target surface;
purging, after the exposing to the precursor gas pulse, substantially all gas from a region directly surrounding the sacrificial layer and the complex target surface; and
exposing, after the purging, in-situ the sacrificial layer and the complex target surface to energetic particles to selective in-situ clean the complex target surface, by desorbing the sacrificial layer and the one or more top layers of atoms linked to the precursor from the precursor gas pulse; and
after the selective in-situ cleaning of the complex target surface, including the sacrificial layer disposed thereon,
repeating the forming a sacrificial layer on the complex target surface followed by the selective in-situ cleaning of the complex target surface, including the sacrificial layer disposed thereon, until determining that the selectively removing the sacrificial layer and one or more top layers of atoms from the in-situ complex target surface has at least one of
completely cleaned the complex target surface; or
completely graded the complex target surface.

20. The method of claim 19, further comprising:
after the selective in-situ cleaning of the complex target surface of the semiconductor substrate followed by determining that the selectively removing the sacrificial layer and one or more top layers of atoms from the in-situ complex target surface has at least one of
completely cleaned the complex target surface, or
completely graded the complex target surface:
forming a gate dielectric layer directly on the cleaned complex target surface.
